(19) United States
(12) Patent Application Publication
(10) Pub. No.: US 2025/0294765 A1
(43) Pub. Date: Sep. 18, 2025

(54) SEMICONDUCTOR MEMORY DEVICE AND MANUFACTURING METHOD OF SEMICONDUCTOR MEMORY DEVICE

(71) Applicant: Kioxia Corporation, Tokyo (JP)

(72) Inventor: Takeshi SAKAGUCHI, Yokkaichi Mie (JP)

(73) Assignee: Kioxia Corporation, Tokyo (JP)

(21) Appl. No.: 18/827,448

(22) Filed: Sep. 6, 2024

(30) Foreign Application Priority Data
Mar. 12, 2024 (JP) 2024-037694

(51) Int. Cl. H10B 43/35; H10B 43/27

(52) U.S. Cl. CPC H10B 43/35; H10B 43/27

(57) ABSTRACT

A semiconductor memory device includes a stacked body in which a plurality of conductive layers is stacked with being separated from each other, and a plate-like portion extending in the stacked body in a stacking direction of the stacked body and in a first direction intersecting with the stacking direction, and penetrating through conductive layers from an uppermost conductive layer to an N-th (N is an integer of 1 or more) conductive layer, among the plurality of conductive layers, in which the plate-like portion includes a wing portion protruding toward the N-th conductive layer, at least at a height position of the N-th conductive layer among the plurality of conductive layers.

### CROSS-REFERENCE TO RELATED APPLICATIONS

This application is based upon and claims the benefit of priority from Japanese Patent Application No. 2024-037694, filed on Mar. 12, 2024; the entire contents of which are incorporated herein by reference.

### FIELD

Embodiments described herein relate generally to a semiconductor memory device and a manufacturing method of a semiconductor memory device.

### BACKGROUND

A semiconductor memory device such as a three-dimensional nonvolatile memory includes a plurality of pillars penetrating through a stacked body in which a plurality of conductive layers is stacked, for example. Portions at which the plurality of conductive layers and the pillars intersect with each other each function as a memory cell. To independently control the memory cells belonging to the respective pillars, one or more conductive layers including an uppermost conductive layer of the stacked body are separated by a plate-like portion.

To arrange the plurality of pillars at high density, the plate-like portion is formed at positions overlapping with several pillars, with chipping the upper ends of the pillars. Nevertheless, there is a problem that electric properties of the pillars partially chipped by overlapping with the plate-like portion deteriorate.

### BRIEF DESCRIPTION OF THE DRAWINGS

FIGS. 1A and 1B are diagrams illustrating a schematic configuration example of a semiconductor memory device according to an embodiment;

FIGS. 2A to 2C are cross-sectional views extending along a Y direction that illustrate an example of a configuration of the semiconductor memory device according to an embodiment;

FIGS. 3A to 3C are diagrams illustrating an example of a configuration of a separating layer of the semiconductor memory device according to an embodiment;

FIGS. 4A to 4C are cross-sectional views extending along the Y direction that sequentially exemplify a part of procedures of a manufacturing method of the semiconductor memory device according to an embodiment;

FIGS. 5A and 5B are cross-sectional views extending along the Y direction that sequentially exemplify a part of procedures of the manufacturing method of the semiconductor memory device according to an embodiment;

FIGS. 6A and 6B are cross-sectional views extending along the Y direction that sequentially exemplify a part of procedures of the manufacturing method of the semiconductor memory device according to an embodiment;

FIGS. 7A and 7B are cross-sectional views extending along the Y direction that sequentially exemplify a part of procedures of the manufacturing method of the semiconductor memory device according to an embodiment;

FIGS. 8A and 8B are cross-sectional views extending along the Y direction that sequentially exemplify a part of procedures of the manufacturing method of the semiconductor memory device according to an embodiment;

FIGS. 9A and 9B are cross-sectional views extending along the Y direction that sequentially exemplify a part of procedures of the manufacturing method of the semiconductor memory device according to an embodiment;

FIGS. 10A and 10B are cross-sectional views extending along the Y direction that sequentially exemplify a part of procedures of the manufacturing method of the semiconductor memory device according to an embodiment;

FIGS. 11A and 11B are cross-sectional views extending along the Y direction that sequentially exemplify a part of procedures of the manufacturing method of the semiconductor memory device according to an embodiment; and

FIGS. 12A to 12F are cross-sectional views extending along the Y direction that sequentially exemplify a part of procedures of the manufacturing method of the semiconductor memory device according to an embodiment.

### DETAILED DESCRIPTION

In general, according to one embodiment, a semiconductor memory device includes a stacked body in which a plurality of conductive layers is stacked with being separated from each other, and a plate-like portion extending in the stacked body in a stacking direction of the stacked body and in a first direction intersecting with the stacking direction, and penetrating through conductive layers from an uppermost conductive layer to an N-th (N is an integer of 1 or more) conductive layer, among the plurality of conductive layers, in which the plate-like portion includes a wing portion protruding toward the N-th conductive layer, at least at a height position of the N-th conductive layer among the plurality of conductive layers.

Exemplary embodiments of the present invention will be explained below in detail with reference to the accompanying drawings. In addition, the present invention is not limited to the following embodiments. Further, components in the following embodiments include components that can be easily conceived by the one skilled in the art, or substantially the same components.

### (Configuration Example of Semiconductor Memory Device)

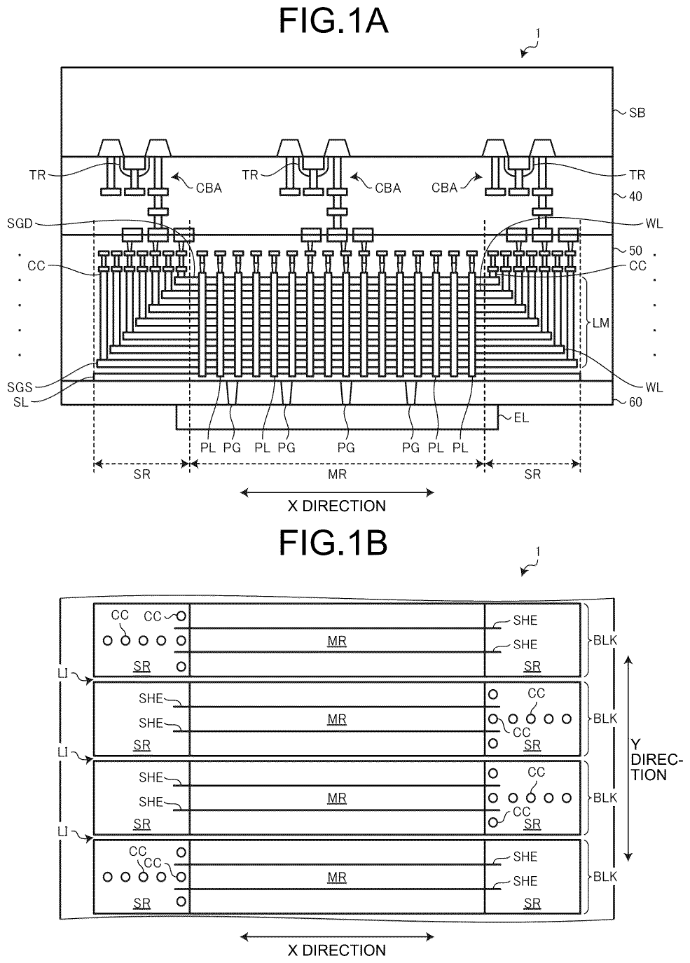

FIGS. 1A and 1B are diagrams illustrating a schematic configuration example of a semiconductor memory device 1 according to an embodiment. More specifically, FIG. 1A is a cross-sectional view extending along an X direction that illustrates the semiconductor memory device 1, and FIG. 1B is a schematic plan view illustrating the layout of the semiconductor memory device 1.

Note that hatching is omitted in FIG. 1A in consideration of visibility of the drawing. Further, in FIG. 1A, components that do not always exist on the same cross section are illustrated, and moreover, partial upper layer wires and the like are omitted.

Further, in this specification, both of the X direction and a Y direction are directions running along the direction of the surface of a word line WL, and the X direction and the Y direction are orthogonal to each other. Further, an electric drawing direction of the word line WL will be sometimes referred to as a first direction, and this first direction is a direction running along the X direction. Further, a direction intersecting with the first direction will be sometimes referred to as a second direction, and this second direction is a direction running along the Y direction. Note that the first direction and the second direction are not always orthogonal to each other because the semiconductor memory device 1 can include a manufacturing error.

As illustrated in FIG. 1A, the semiconductor memory device 1 includes, in order from a paper surface lower side, an electrode film EL, a source line SL, one or more selection gate lines SGS, a plurality of word lines WL, one or more selection gate lines SGD, and a semiconductor board SB provided with a peripheral circuit CBA.

The source line SL is arranged on the electrode film EL via an insulating layer 60. A plurality of plugs PG is arranged in the insulating layer 60, and the source line SL and the electrode film EL keep electric conduction via the plugs PG. An electrode pad (not illustrated) for supplying power and signals to the semiconductor memory device 1 from the outside is provided on the same layer as the electrode film EL. The selection gate lines SGS, the plurality of word lines WL, and the selection gate lines SGD are stacked in this order on the source line SL, and a stacked body LM is thereby formed.

As illustrated in FIGS. 1A and 1B, a memory region MR is arranged at the central portion in the X direction of the plurality of word lines WL, and step regions SR are respectively arranged at both ends in the X direction of the plurality of word lines WL. In addition, in this specification, a direction in which a terrace surface of the word line WL in each step in the step region SR is oriented is defined as an up direction in the semiconductor memory device 1.

The memory region MR and the step regions SR are divided into a plurality of regions by a plurality of plate-like contacts LI penetrating through the plurality of word lines WL and the like, and extending in a direction running along the X direction. A region that is arranged between the plate-like contacts LI neighboring in the Y direction, and includes the memory region MR and the step regions SR will be referred to as a block region BLK. As described layer, the memory region MR includes a plurality of memory cells holding data in a nonvolatile manner, and the above-described block region BLK is an erasing unit of these pieces of data.

Further, a plurality of separating layers SHE penetrating through the selection gate lines SGD and extending along a direction running along the X direction is arranged between the plate-like contacts LI neighboring in the Y direction. The plurality of separating layers SHE extends in the direction running along the X direction, over the entire memory region MR, and reaches a part of the step regions SR at both ends in the X direction.

A plurality of pillars PL penetrating through the word lines WL and the selection gate lines SGD and SGS in the stacking direction is arranged in the memory region MR. Lower ends of the pillars PL reach the source line SL. The plurality of memory cells is formed at intersections between the pillars PL and the word line WL. The semiconductor memory device 1 is thereby formed as a three-dimensional nonvolatile memory in which memory cells are three-dimensionally arranged in the memory region MR, for example.

In the step regions SR, the plurality of word lines WL and the selection gate lines SGD and SGS are terminated with being processed in a staircase pattern. At this time, because the plurality of word lines WL and the selection gate lines SGD and SGS constituting a terrace portion shifts from an upper layer side to a lower layer side as getting away from the memory region MR in the X direction, a height position of the terrace portion declines toward the source line SL side.

In addition, the above-described separating layers SHE extend from the memory region MR up to the portions of the step regions SR in which the selection gate lines SGD are processed in a staircase pattern. The selection gate lines SGD are thereby separated into a plurality of regions within one block region BLK. In other words, by the separating layers SHE penetrating through upper layer portions existing superior to the plurality of word lines WL, these upper layer portions are segmented into patterns of the plurality of selection gate lines SGD. The separating layers having such a configuration serve as an example of the plate-like portion.

In the terrace portion on each step formed by the plurality of word lines WL and the selection gate lines SGD and SGS, a contact CC connecting to the word line WL and the selection gate lines SGD and SGS in each layer is individually arranged. In the word lines WL and the selection gate line SGS, one contact CC is connected for one layer. In the selection gate lines SGD, for one layer, for each section separated by the separating layers SHE, one contact CC is connected.

Here, in one block region BLK, a plurality of contacts CC is arranged on one side out of the X direction both sides of the step regions SR. Further, when viewed from one side in the X direction, for example, a plurality of contacts CC is arranged for every two block regions BLK.

That is, in the example in FIG. 1B, in the block region BLK in the paper surface uppermost part, a plurality of contacts CC is arranged in the step region SR on the paper surface left side, for example, out of the step regions SR at the X direction both ends. Further, in the block region BLK existing immediately below the above-described block region BLK, and the block region BLK existing further below the block region BLK, a plurality of contacts CC is arranged in the step region SR on the paper surface right side out of the step regions SR at the X direction both ends. Furthermore, in the block region BLK in the paper surface lowermost part, a plurality of contacts CC is arranged again in the step region SR on the paper surface left side.

Accordingly, the contacts CC in the step regions SR at the X direction both ends that are illustrated in FIG. 1A belong to different block regions BLK, and are not actually positioned in the same cross section.

The word lines WL and the like stacked in a multilayered manner are individually drawn by these contacts CC. More specifically, from these contacts CC, a writing voltage, a readout voltage, and the like are applied to memory cells included in the memory region MR at the central portion of the plurality of word lines WL, via the word lines WL at the same height position as the memory cells.

The plurality of word lines WL and the selection gate lines SGD and SGS, the pillars PL, and the contacts CC are covered with an insulating layer 50. The insulating layer 50 extends also up to the periphery of these components.

The semiconductor board SB existing above the insulating layer 50 is a silicon substrate or the like, for example. The peripheral circuit CBA including a transistor TR, a wire, and the like is arranged on the surface of the semiconductor board SB. Various voltages applied from the contacts CC to memory cells are controlled by the peripheral circuit CBA electrically connected with these contacts CC. The peripheral circuit CBA thereby controls electrical operations of the memory cells.

The peripheral circuit CBA is covered with an insulating layer 40, and by bonding the insulating layer 40 and the insulating layer 50 covering the plurality of word lines WL and the like, the semiconductor memory device 1 including components such as the plurality of word lines WL and the selection gate lines SGD and SGS, the pillars PL, the contacts CC, and the like, and the peripheral circuit CBA is formed.

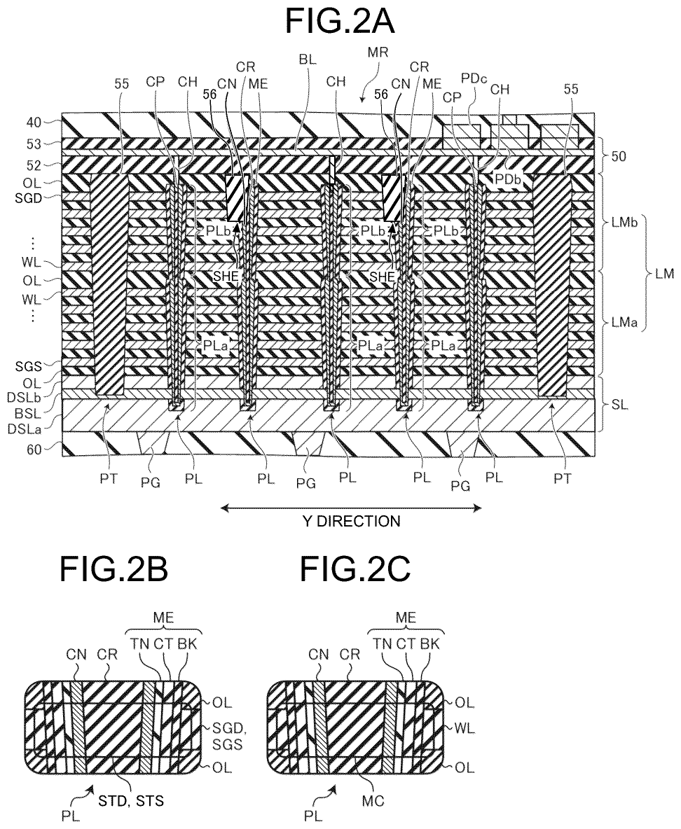

Next, a detailed configuration example of the semiconductor memory device 1 will be described with reference to FIGS. 2A to 2C. FIGS. 2A to 2C are cross-sectional views extending along the Y direction that illustrate an example of a configuration of the semiconductor memory device 1 according to an embodiment.

More specifically, FIG. 2A is a cross-sectional view of the semiconductor memory device 1 in the memory region MR. In FIG. 2A, a structure existing below the insulating layer 60 and a structure existing above an insulating layer 53 to be described later are omitted. FIG. 2B is an enlarged cross-sectional view of the pillar PL at a height position of the selection gate lines SGD and SGS. FIG. 2C is an enlarged cross-sectional view of the pillar PL at a height position of the word line WL.

As illustrated in FIG. 2A, the source line SL has a multilayer structure in which, for example, a lower source line DSLa, an intermediate source line BSL, and an upper source line DSLb are stacked in this order on the insulating layer 60. In addition, the intermediate source line BSL is arranged in a lower portion of the memory region MR of the stacked body LM.

The lower source line DSLa, the intermediate source line BSL, and the upper source line DSLb are, for example, polysilicon layers, or the like. Among these, at least the intermediate source line BSL may be a conductive polysilicon layer in which impurities are dispersed, or the like.

In addition, the source line SL is connected to the peripheral circuit CBA via the electrode film EL by a feedthrough contact (not illustrated) extending from the electrode film EL to the peripheral circuit CBA in the above-described insulating layer 50 on the outside of the stacked body LM.

The stacked body LM is arranged on the source line SL. The stacked body LM includes stacked bodies LMa and LMb in which the plurality of word lines WL and a plurality of insulating layers OL are alternately stacked for one layer.

The stacked body LMa is arranged above the source line SL. In a lower layer further inferior to the word line WL in the lowermost layer of the stacked body LMa, one or more selection gate lines SGS are arranged via the insulating layers OL. The stacked body LMb is arranged on the stacked body LMa. In an upper layer further superior to the word line WL in the uppermost layer of the stacked body LMb, one or more selection gate lines SGD are arranged via the insulating layers OL.

The numbers of these word lines WL and the selection gate lines SGD and SGS to be stacked in the stacked body LM are an arbitrary number. The word lines WL and the selection gate lines SGD and SGS are, for example, tungsten layers, molybdenum layers, or the like. The insulating layers OL are, for example, oxide silicon layers or the like. In addition, the uppermost insulating layer OL in each of the stacked bodies LMa and LMb may be formed to become thicker than the other insulating layers OL.

The top surface of the stacked body LM is covered with an insulating layer 52. The insulating layer 52 is covered with the insulating layer 53. The insulating layers 52 and 53 both constitute a part of the insulating layer 50 in FIG. 1A together with an insulating layer 51 to be described later.

As described above, the stacked body LM is divided in the Y direction by the plurality of plate-like contacts LI. That is, the plate-like contacts LI are arranged adjacently to each other in the Y direction, and extend in the stacking direction of the stacked body LM and the direction running along the X direction.

In this manner, the plate-like contacts LI continuously extend in the stacked body LM from one end in the X direction of the stacked body LM toward a different end. Further, the plate-like contacts LI penetrate through the stacked body LM and the upper source line DSLb, and reach the intermediate source line BSL in the memory region MR.

Further, the plate-like contacts LI each have a tapered shape in which a width in the Y direction gets smaller from an upper end toward a lower end, for example. Alternatively, the plate-like contacts LI have a bowing shape in which a width in the Y direction becomes the largest at a predetermined position between the upper end and the lower end, for example.

The plate-like contacts LI each include an insulating layer 54 and a conductive layer 24. The insulating layer 54 is, for example, an oxide silicon layer or the like. The conductive layer 24 is, for example, a tungsten layer, a conductive polysilicon layer, or the like.

The insulating layer 54 covers side walls of the plate-like contacts LI that face each other in the Y direction. The conductive layer 24 is charged inside the insulating layer 54, and electrically connected to the source line SL including the intermediate source line BSL. Note that, by a plate-like member, into which an insulating layer is charged, penetrating through the stacked body LM and extending in the direction running along the X direction, the plate-like member may divide the stacked body LM in the Y direction in place of the plate-like contacts LI.

Further, the plurality of separating layers SHE penetrating through the upper layer portion of the stacked body LMb and extending in the direction running along the X direction is arranged between the plate-like contacts LI neighboring in the Y direction. These separating layers SHE are insulating layers 56 such as oxide silicon layers that penetrate through at least the selection gate lines SGD and extend in the stacked body LMb.

In other words, by these separating layers SHE penetrating through the upper layer portion of the stacked body LMb, and extending in the X direction in the memory region MR and a part of the step regions SR between the plate-like contacts LI, the upper layer portion of the stacked body LMb is segmented by the selection gate lines SGD.

Here, the separating layers SHE extend in the stacked body LM in the direction running along the X direction, at positions overlapping with upper ends on one side in the Y direction of partial pillars PL, in the stacking direction of the stacked body LM. By being arranged at the positions overlapping with the separating layers SHE, upper ends on one side in the Y direction of these partial pillars PL are chipped.

In the memory region MR, the plurality of pillars PL penetrating through the stacked body LM, the upper source line DSLb, and the intermediate source line BSL, and reaching the lower source line DSLa is arranged in a dispersed manner.

The plurality of pillars PL has staggered arrangement, for example, when viewed from the stacking direction of the stacked body LM. In addition, by arranging the plurality of pillars PL in such a manner that the separating layers SHE and the partial pillars PL overlap with each other as described above, for example, it is possible to maintain periodic arrangement such as staggered arrangement of the plurality of pillars PL, and increase a memory capacity by arranging the pillars PL at high density.

Each of the pillars PL has a shape such as a circle, an ellipse, or an oval coin shape (oval shape), for example, as a cross-sectional shape in a direction running along a layer direction of the stacked body LM, that is to say, a direction running along an XY plane.

Further, the pillar PL includes a pillar PLa penetrating through the stacked body LMa, and a pillar PLb penetrating through the stacked body LMb. The pillars PLa and PLb each have a tapered shape with a diameter and a cross-sectional area getting smaller from the upper layer side toward the lower layer side. Alternatively, the pillars PLa and PLb each have a bowing shape with a diameter and a cross-sectional area becoming the largest at a predetermined position between the upper layer side and the lower layer, for example.

The plurality of pillars PL each include a memory layer ME extending in the stacked body LM in the stacking direction, a channel layer CN penetrating through the inside of the stacked body LM and connecting with the intermediate source line BSL, a cap layer CP covering the top surface of the channel layer CN, and a core layer CR serving as a core material of the pillars PL.

As illustrated in FIGS. 2B and 2C, the memory layer ME has a multilayer structure in which a block insulating layer BK, a charge accumulation layer CT, and a tunnel insulating layer TN are stacked in this order from the outer peripheral side of the pillar PL. More specifically, the memory layer ME is arranged on the side surface of the pillar PL that excludes a depth position of the intermediate source line BSL. Further, the memory layer ME is arranged also on the bottom surface of the pillar PL reaching the depth of the lower source line DSLa.

The channel layer CN penetrates through the stacked body LM, the upper source line DSLb, and the intermediate source line BSL, and reaches the depth of the lower source line DSLa on the inside of the memory layer ME. More specifically, the channel layer CN is arranged on the side surface and the bottom surface of the pillar PL via the memory layer ME. Note that a part of the channel layer CN has contact with the intermediate source line BSL on the side surface, and the channel layer CN is thereby electrically connected to the source line SL including the intermediate source line BSL. The core layer CR is charged on the further inside of the channel layer CN.

Further, the plurality of pillars PL each include the cap layer CP at the upper end. The cap layer CP is arranged at the upper end of the pillar PL in such a manner as to cover at least the upper end of the channel layer CN, and connected with the channel layer CN. Further, the cap layer CP is connected with a bit-line BL arranged in the insulating layer 53, via a plug CH arranged in the insulating layer 52. The bit-line BL extends in an upper portion of the stacked body LM in a direction running along the Y direction, in such a manner as to intersect with a drawing direction of the word line WL.

In addition, in FIG. 2A, the plug CH is connected only to the three pillars PL respectively penetrating through the selection gate lines SGD separated into three, and electrically connected to the bit-line BL illustrated in FIG. 2A, among the five pillars PL. The other pillars PL are connected via the plug CH not illustrated in FIG. 2A, to another bit-lines BL extending in a direction running along the Y direction, concurrently with the bit-line BL illustrated in FIG. 2A, at a position different from the cross section illustrated in FIG. 2A.

The block insulating layer BK, the tunnel insulating layer TN, and the core layer CR of the memory layer ME are, for example, oxide silicon layers or the like. The charge accumulation layer CT of the memory layer ME is a silicon nitride layer or the like, for example. The channel layer CN and the cap layer CP are semiconductor layers such as polysilicon layers or amorphous silicon layers, for example.

As illustrated in FIG. 2C, with the above-described configuration, a memory cell MC is formed at a portion of the side surface of the pillar PL that faces each word line WL. By a predetermined voltage being applied from the word line WL, data writing and readout are performed into and from the memory cell MC.

Further, as illustrated in FIG. 2B, a selection gate STD is formed at a portion at which the side surface of the pillar PL faces the selection gate line SGD in an upper layer superior to the word line WL. Further, a selection gate STS is formed at a portion at which the side surface of the pillar PL faces the selection gate line SGS in a lower layer inferior to the word line WL.

By predetermined voltages being applied from the selection gate lines SGD and SGS, the selection gates STD and STS are turned on or off, and the memory cells MC of the pillars PL to which the selection gates STD and STS belong can be brought into a selected state or an unselected state.

In addition, in the pillar PL that is arranged at a position overlapping with the separating layer SHE, and has a chipped upper end on one side, the function of the selection gate line SGD is fulfilled in a remaining one side portion on the other side in the Y direction.

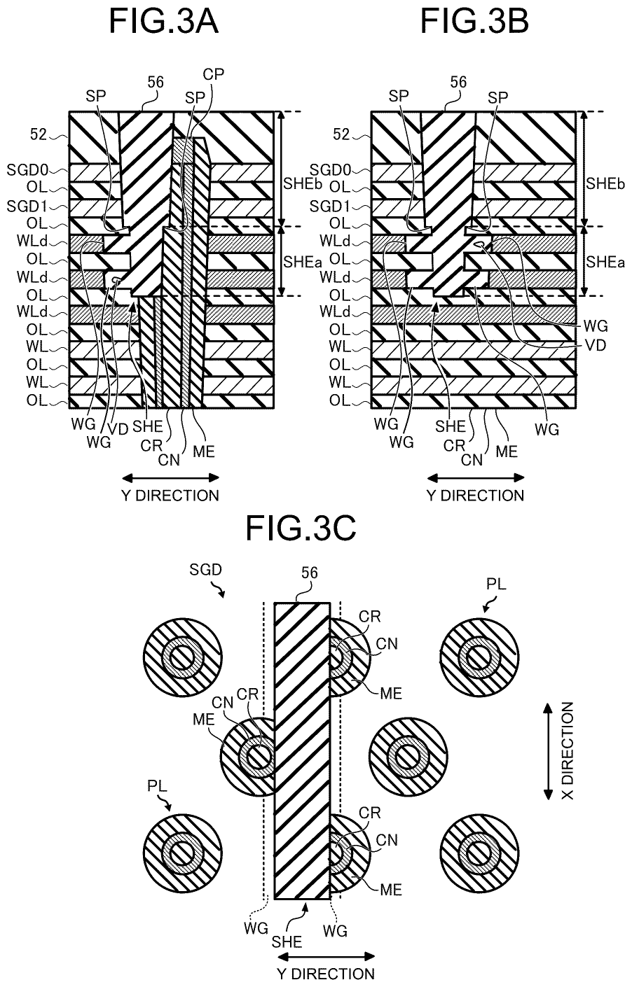

Next, a detailed configuration example of the separating layer SHE included in the semiconductor memory device 1 will be described with reference to FIGS. 3A to 3C.

FIGS. 3A to 3C are diagrams illustrating an example of a configuration of the separating layer SHE of the semiconductor memory device 1 according to an embodiment. More specifically, FIG. 3A is an enlarged cross-sectional view extending along the Y direction that illustrates the separating layer SHE, and FIG. 3B is an enlarged cross-sectional view extending along the Y direction that illustrates the separating layer SHE in a cross-section different from that in FIG. 3A. FIG. 3C is an XY cross-sectional view at a height position of an arbitrary selection gate line SGD.

As illustrated in FIGS. 3A and 3B, the stacked body LM includes, as an upper layer wiring structure, one or more selection gate lines SGD, a plurality of word lines WL, and one or more word lines WLd arranged between the selection gate line SGD in the lowermost layer and the word line WL in the uppermost layer.

In the example illustrated in FIGS. 3A and 3B, the stacked body LM includes, in order from the upper layer side, two selection gate lines SGD0 and SGD1, three word lines WLd, and a plurality of word lines WL. Note that the stacked body LM may include three or more selection gate lines SGD, and may include two or less or four or more word lines WLd.

The word line WLd is a dummy word line, and does not have a function as a gate electrode that drives the memory cell MC. Different voltage can be applied by the selection gate line SGD and the word line WL to the selection gate STD and the memory cell MC having different functions. By arranging the dummy word line WLd between the selection gate lines SGD and the word lines WL, the influence of electric fields on each other in the selection gate STD and the memory cell MC is mitigated.

In the example illustrated in FIGS. 3A and 3B, the separating layer SHE penetrates through the selection gate lines SGD0 and SGD1 and also penetrates through the two word lines WLd on the upper layer side among the three word lines WLd to reach a depth position of the insulating layer OL arranged immediately below the two word lines WLd.

Further, the separating layer SHE includes a wing portion WG protruding toward the word line WLd, at a height position of the word line WLd. More specifically, as in the cross-section illustrated in FIG. 3A, in a portion in which the separating layer SHE overlaps with an upper end on one side in the Y direction of the pillar PL, the wing portion WG protrudes toward the word line WLd only on the Y direction one side. On the other hand, as in the cross-section illustrated in FIG. 3B, in a portion in which the separating layer SHE does not overlap with the pillar PL, the wing portion WG of the separating layer SHE protrudes toward the word line WLd on both sides in the Y direction of the separating layer SHE.

In addition, the separating layer SHE including the wing portion WG may partially include a void. That is to say, the insulating layer 56 to be charged into the separating layer SHE may include an uncharged portion at a part of a portion in which the separating layer SHE penetrates through the stacked body LM to a predetermined depth, or at a part of the wing portion WG. FIGS. 3A and 3B exemplify a state in which the wing portion WG partially includes a void VD.

Here, the separating layer SHE includes a lower layer side portion SHEa having the wing portion WG, and an upper layer side portion SHEb not having the wing portion WG. In the example illustrated in FIGS. 3A and 3B, a portion from the upper end of the separating layer SHE to some midpoint in the insulating layer OL arranged immediately below the selection gate line SGD 1 in the lowermost layer corresponds the upper layer side portion SHEb, and a lower portion to the lowermost end portion of the separating layer SHE (i.e., some midpoint in the insulating layer OL arranged immediately below the second word line WLd) corresponds to the lower layer side portion SHEa.

A width at the upper end of the lower layer side portion SHEa of the separating layer SHE in the Y direction is narrower than a width at the lower end of the upper layer side portion SHEb in the Y direction. The separating layer SHE accordingly includes a step SP at a boundary portion between the lower layer side portion SHEa and the upper layer side portion SHEb.

As illustrated in FIG. 3C, as described above, the plurality of pillars PL is arranged in a staggered manner, for example, when viewed from the stacking direction of the stacked body LM. In a case where the arrangement of these pillars PL is regarded as the pillars PL on a plurality of rows extending in the X direction, because the plurality of pillars PL has staggered arrangement as a whole, pillars PL on two rows neighboring each other are arranged without overlapping with each other in the X direction.

The separating layer SHE extends in the direction running along the X direction, between the pillars PL on the two rows neighboring each other, among the pillars PL on the plurality of rows. With this configuration, the upper end of the pillar PL belonging to a row on one side in the Y direction with respect to the separating layer SHE is chipped on a side facing a row on the other side in the Y direction. Further, the upper end of the pillar PL belonging to a row on the other side in the Y direction with respect to the separating layer SHE is chipped on a side facing a row on the one side in the Y direction.

As described above, on both sides in the Y direction of the separating layer SHE extending in the direction running along the X direction, pillars PL whose upper ends on one side are chipped are alternately arranged.

### (Manufacturing Method of Semiconductor Memory Device)

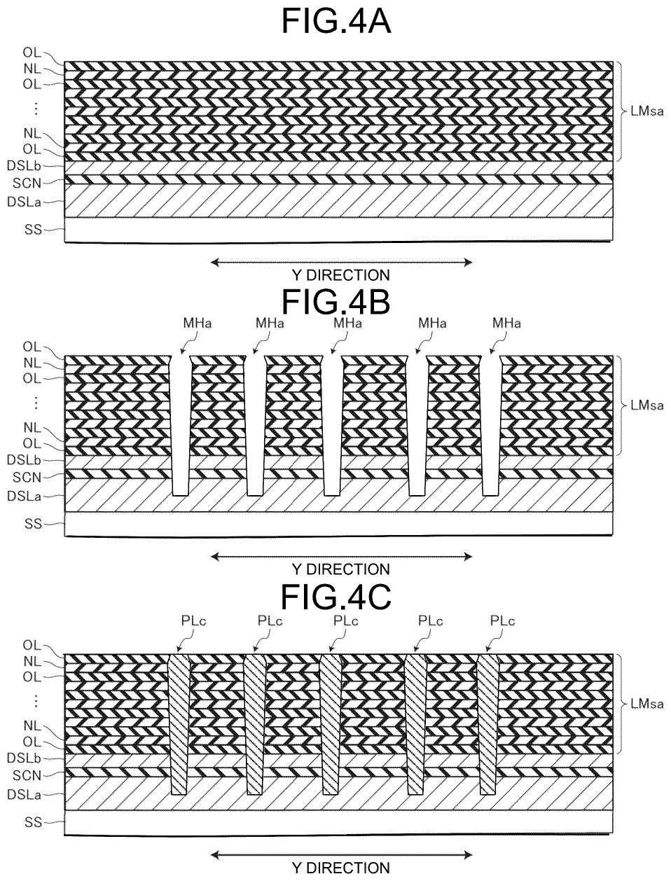

Next, a manufacturing method of the semiconductor memory device 1 of the embodiment will be described with reference to FIGS. 4A to 12F. FIGS. 4A to 12F are cross-sectional views extending along the Y direction that sequentially exemplify a part of procedures of the manufacturing method of the semiconductor memory device 1 according to an embodiment.

First of all, FIGS. 4A to 4C illustrate a procedure of forming a component latterly becoming a part of the pillar PL.

As illustrated in FIG. 4A, the lower source line DSLa, an intermediate sacrificial layer SCN, and the upper source line DSLb are formed in this order on a support substrate SS.

The support substrate SS may be, for example, a semiconductor substrate such as a silicon substrate, an insulating substrate such as a ceramic substrate, a quartz substrate, or a sapphire substrate, a conductive substrate, or the like. The lower source line DSLa and the upper source line DSLb are, for example, polysilicon layers, or the like. The intermediate sacrificial layer SCN is a layer that is latterly replaced with a polysilicon layer or the like to become the intermediate source line BSL.

A stacked body LMsa in which a plurality of insulating layers NL and a plurality of insulating layers OL are alternately stacked for one layer is formed on the upper source line DSLb. The insulating layer NL is, for example, a silicon nitride layer or the like, and functions as a sacrificial layer to be replaced with a conductive material that latterly becomes the word line WL or the selection gate line SGS. The stacked body LMsa is a portion that latterly becomes the stacked body LMa by such replacement processing.

In addition, at this stage, the plurality of insulating layers OL including the uppermost insulating layer OL may have an approximately equal thickness.

After that, for example, both ends in the X direction of the stacked body LMsa are processed in a staircase pattern, and the lower layer side portions of the step regions SR are formed, which is not illustrated. Such processing of the stacked body LMsa is performed by alternately repeating etching of a pair of insulating layers ON and NL and slimming of a photoresist layer a plurality of times, using a photoresist layer or the like that partially covers the top surface of the stacked body LMsa, as a mask.

The formed lower layer side portions of the step regions SR are covered with an insulating layer such as an oxide silicon layer that constitutes a part of the above-described insulating layer 50 (refer to FIG. 1A).

As illustrated in FIG. 4B, a plurality of memory holes MHa that penetrates through the stacked body LMsa, the upper source line DSLb, and the intermediate sacrificial layer SCN, and reaches the lower source line DSLa is formed. These memory hole MHa are portions that latterly become the pillars PLa.

As illustrated in FIG. 4C, for example, sacrificial layers such as amorphous silicon layers are charged into the memory holes MHa, and a plurality of pillars PLC is formed.

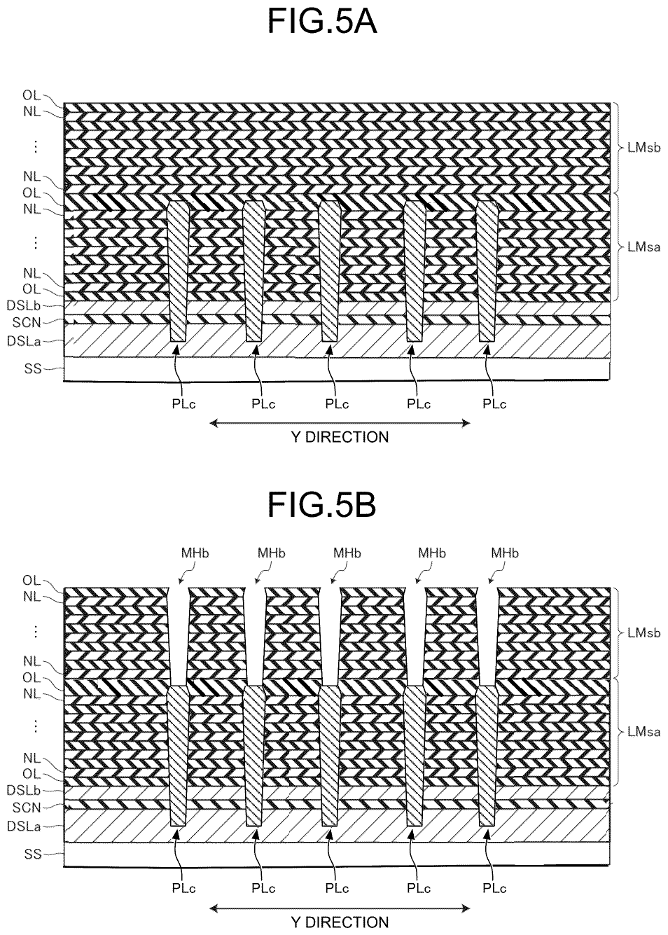

Next, FIGS. 5A to 7B illustrate a procedure of forming the pillars PL.

As illustrated in FIG. 5A, an oxide silicon layer or the like is further stacked on the top surface of the stacked body LMsa. The uppermost insulating layer OL of the stacked body LMsa thereby becomes thicker than the other insulating layers OL. Further, the upper ends of the pillars PLc are buried in the uppermost insulating layer OL.

Further, a stacked body LMsb in which a plurality of insulating layers NL and a plurality of insulating layers OL are alternately stacked for one layer is formed on the stacked body LMsa. The stacked body LMsb is a portion that latterly becomes the stacked body LMb by the insulating layer NL being latterly replaced with the word line WL or the selection gate line SGD.

In addition, at this stage, the plurality of insulating layers OL of the stacked body LMsb that includes the uppermost insulating layer OL may have an approximately equal thickness.

After that, for example, both ends in the X direction of the stacked body LMsb are processed in a staircase pattern in such a manner as to be contiguous to the lower layer side portions of the step regions SR, and the upper layer side portions of the step regions SR are formed, which is not illustrated. Similarly to the lower layer side portions of the step regions SR, such processing of the stacked body LMsb is performed by alternately repeating etching of a pair of insulating layers ON and NL and slimming of a photoresist layer a plurality of times, using a photoresist layer or the like that partially covers the top surface of the stacked body LMsb, as a mask.

The formed upper layer side portions of the step regions SR are covered with an insulating layer such as an oxide silicon layer that constitutes a part of the above-described insulating layer 50 (refer to FIG. 1A).

As illustrated in FIG. 5B, a plurality of memory holes MHb penetrating through the stacked body LMsb, and respectively reaching the upper ends of the plurality of pillars PLC arranged in the stacked body LMsa is formed. These memory holes MHb are portions that latterly become the pillars PLb.

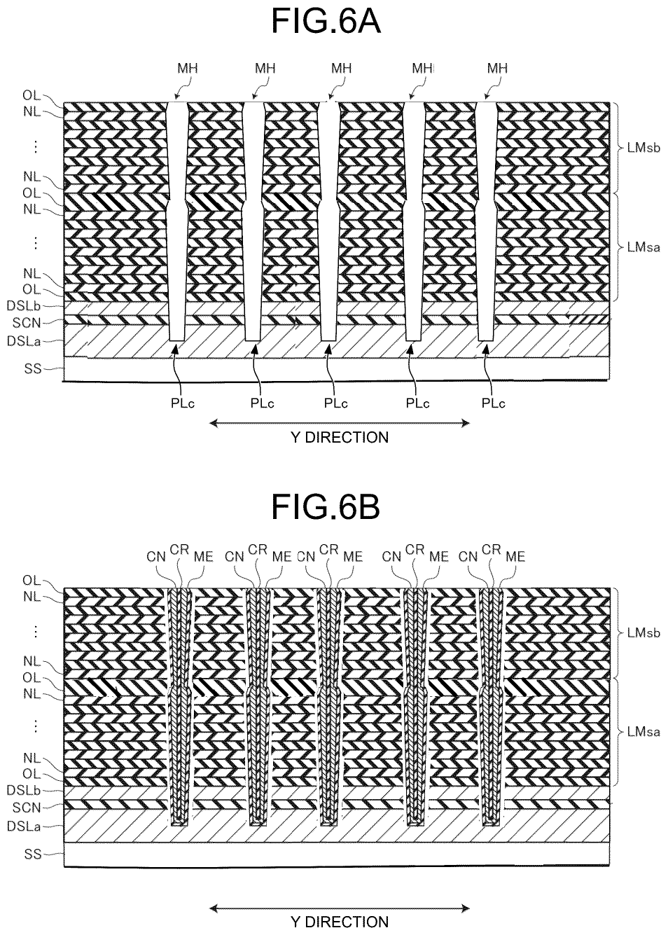

As illustrated in FIG. 6A, via the plurality of memory holes MHb, sacrificial layers are removed from the plurality of pillars PLC connected to their respective lower ends. A plurality of memory holes MH penetrating through the stacked bodies LMsa and LMsb and reaching the source line SL is thereby formed.

As illustrated in FIG. 6B, in each of the plurality of memory holes MH, the memory layer ME having a stacked structure including, in order from the outer periphery side of the memory hole MH, the block insulating layer BK, the charge accumulation layer CT, and the tunnel insulating layer TN (refer to FIGS. 2B and 2C) is formed.

Further, the channel layers CN are formed on the side walls and the bottom surfaces of the plurality of memory holes MH via the memory layers ME. Further, the core layer CR is formed by charging an oxide silicon layer or the like into an air gap in the memory hole MH that exists on the inner side of the channel layer CN.

At this time, the memory layer ME, the channel layer CN, and the core layer CR are formed also on the top surface of the stacked body LMsb. The memory layer ME, the channel layer CN, and the core layer CR are removed from the top surface of the stacked body LMsb by etch back or the like.

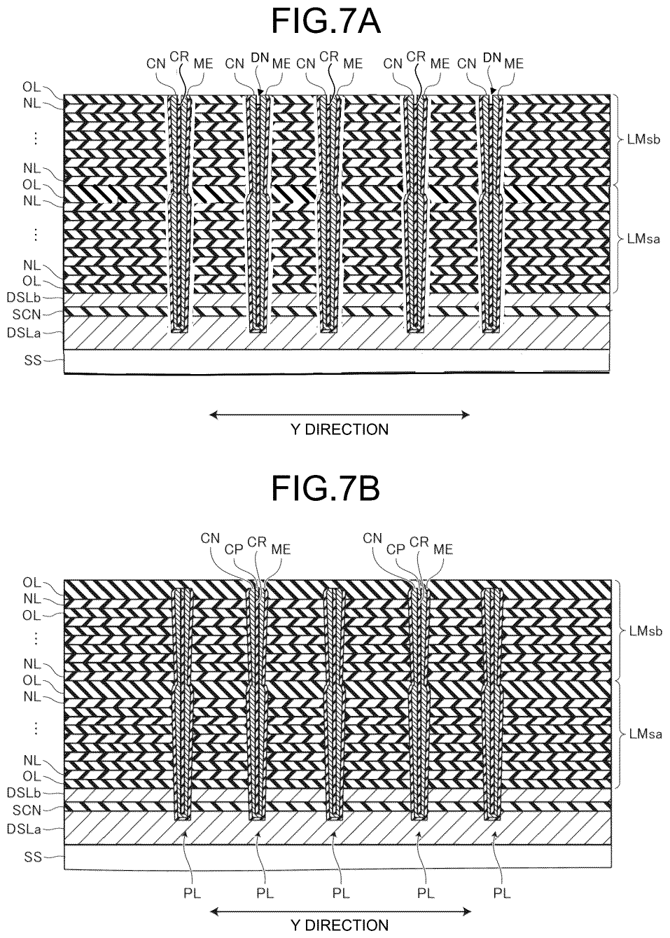

As illustrated in FIG. 7A, when etch back of the core layer CR on the top surface of the stacked body LMsb is performed, by retracting the upper end of the core layer CR in a depth direction of the memory hole MH by further excess etch back, a recess DN is formed at the upper end of the memory hole MH.

As illustrated in FIG. 7B, the cap layer CP is formed by charging a semiconductor layer into the recess DN at the upper end of the memory hole MH.

Further, an oxide silicon layer or the like is further stacked on the top surface of the stacked body LMsb. The uppermost insulating layer OL of the stacked body LMsb thereby becomes thicker than the other insulating layers OL. Further, the upper ends of the pillars PL are buried in the uppermost insulating layer OL.

As described above, a plurality of pillars PL is formed. Note that, at this time point, the memory layers ME cover the entire side walls of the plurality of pillars PL, and a state in which the channel layers CN are exposed is not caused.

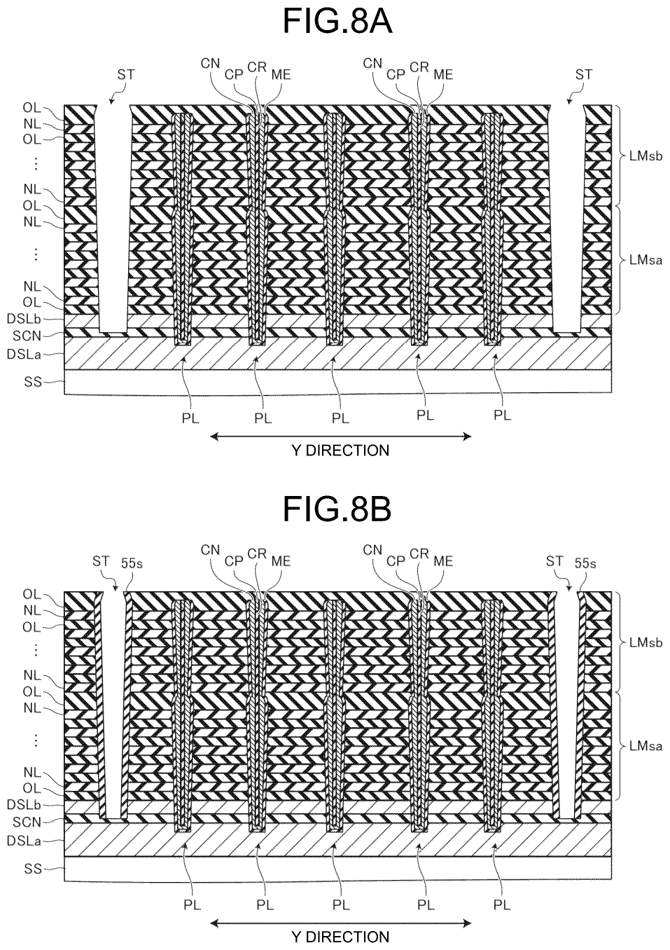

Next, FIGS. 8A to 11B illustrate a procedure of forming the source line SL, the word line WL, and the like.

As illustrated in FIG. 8A, a slit ST penetrating through the stacked bodies LMsa and LMsb, and the upper source line DSLb, and reaching the intermediate sacrificial layer SCN is formed.

The slit ST extends in the stacked bodies LMsa and LMsb also in the direction running along the X direction (i.e., direction vertical to a paper surface). The slit ST is a component that latterly becomes the plate-like contact LI, in addition to being used in replacement processing to be described below.

As illustrated in FIG. 8B, insulating layers 55s are formed on the side walls of the slit ST that face each other in the Y direction. The insulating layer 55s is an oxide silicon layer or the like, for example, and unlike the above-described insulating layer 55 (refer to FIG. 2A) that latterly constitutes the plate-like contact LI, is a tentative protective layer formed to protect the stacked bodies LMsa and LMsb in subsequent processing.

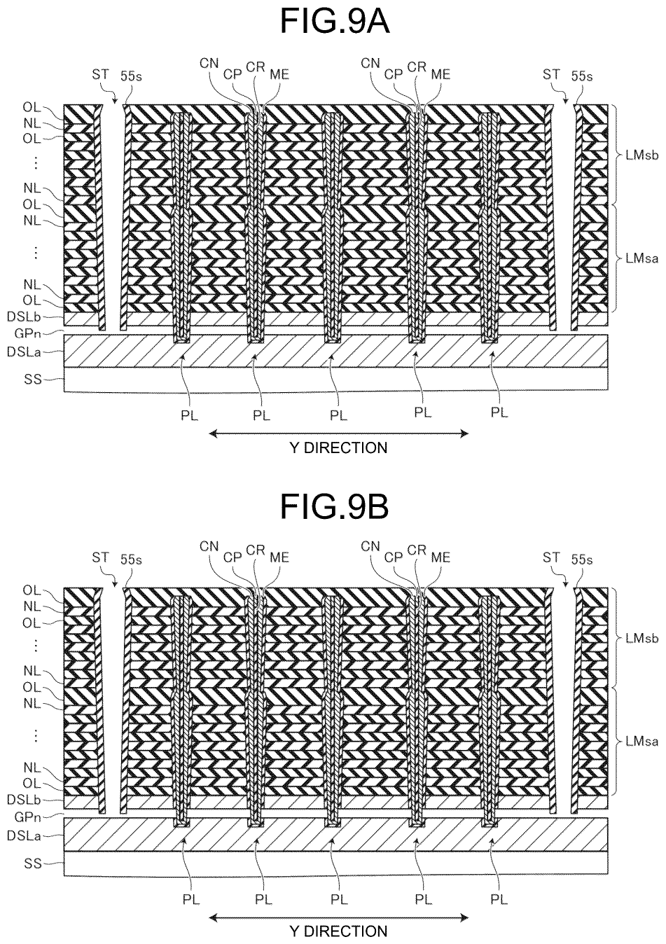

As illustrated in FIG. 9A, the intermediate sacrificial layer SCN sandwiched between the lower source line DSLa and the upper source line DSLb is removed by flowing removal liquid of the intermediate sacrificial layer SCN such as hot phosphoric acid, for example, via the slit ST of which the side walls are protected by the insulating layers 55s.

A gap layer GPn is thereby formed between the lower source line DSLa and the upper source line DSLb. Further, a part of the memory layer ME in the outer periphery portion of the pillar PL is exposed to the inside of the gap layer GPn.

At this time, because the side walls of the slit ST are protected by the insulating layers 55s, the insulating layers NL in the stacked bodies LMsa and LMsb are prevented from being removed.

As illustrated in FIG. 9B, by appropriately flowing medicinal solution into the gap layer GPn via the slit ST, the block insulating layer BK, the charge accumulation layer CT, and the tunnel insulating layer TN (refer to FIGS. 2B and 2C) of the memory layer ME exposed to the inside of the gap layer GPn are sequentially removed.

The memory layer ME is thereby removed from a part of the side walls of the pillar PL, and a part of the inside channel layer CN is exposed to the inside of the gap layer GPn.

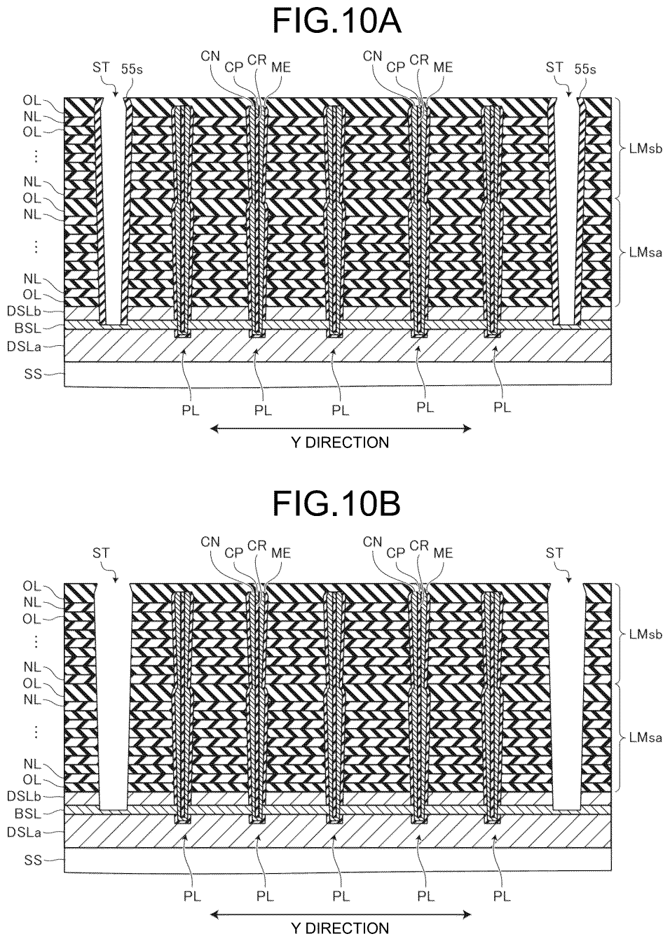

As illustrated in FIG. 10A, from the slit ST of which the side walls are protected by the insulating layers 55s, raw material gas such as amorphous silicon, for example, is injected, and amorphous silicon or the like is charged into the gap layer GPn. Further, by heat-treating the support substrate SS, and making amorphous silicon charged into the gap layer GPn, polycrystalline, the intermediate source line BSL containing polysilicon or the like is formed.

A part of the channel layer CN of the pillar PL is thereby connected with the source line SL on the side surface via the intermediate source line BSL.

As illustrated in FIG. 10B, the insulating layers 55s are removed from the side walls of the slit ST.

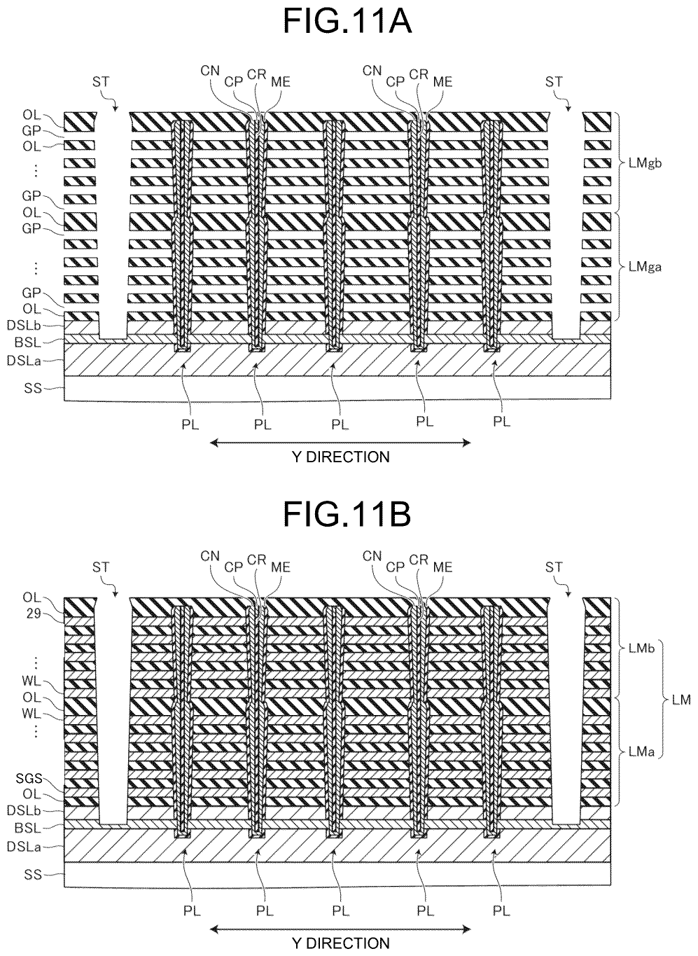

As illustrated in FIG. 11A, by flowing removal liquid of the insulating layers NL such as hot phosphoric acid, for example, from the slit ST into the stacked bodies LMsa and LMsb, the insulating layers NL in the stacked bodies LMsa and LMsb are removed. Stacked bodies LMga and LMgb including a plurality of gap layers GP from which the insulating layers NL between the insulating layers OL are removed are thereby formed.

The stacked bodies LMga and LMgb including a plurality of gap layers GP have a weak structure. The plurality of pillars PL supports such weak stacked bodies LMga and LMgb. By being supported by these pillars PL, the remaining insulating layers OL are prevented from warping, and the stacked bodies LMga and LMgb itself are prevented from becoming distorted or collapsing.

As illustrated in FIG. 11B, the plurality of word lines WL and the like are formed by injecting raw material gas of a conductive material such as tungsten or molybdenum, for example, into the stacked bodies LMga and LMgb from the slit ST, and charging the conductive material into the gap layers GP in the stacked bodies LMga and LMgb.

The stacked body LM including the stacked body LMa and the stacked body LMb in which the plurality of word lines WL and a plurality of insulating layers OL are alternately stacked for one layer is thereby formed. In addition, FIG. 11B illustrates a procedure of forming one or more conductive layers 29 on the upper layer side of the stacked body LM. These conductive layers 29 are segmented into patterns of the selection gate lines SGD by the separating layer SHE to be formed in subsequent processing.

As described above, processing of forming the intermediate source line BSL from the intermediate sacrificial layer SCN, and processing of forming the word line WL from the insulating layer NL will also be referred to as the replacement processing.

After that, the plate-like contact LI is formed by charging insulating layer 55 into the slit ST. Further, the contacts CC (refer to FIGS. 1A and 1B) to be connected to the respective word line WL or the like are formed by causing the contacts CC to penetrate through the insulating layers covering the step region SR. Further, a groove penetrating through the conductive layers 29 on the upper layer side of the stacked body LM is formed, and the separating layer SHE is formed by charging the insulating layers 56 into the groove, and the conductive layers 29 are segmented into patterns of the selection gate lines SGD by the separating layer SHE.

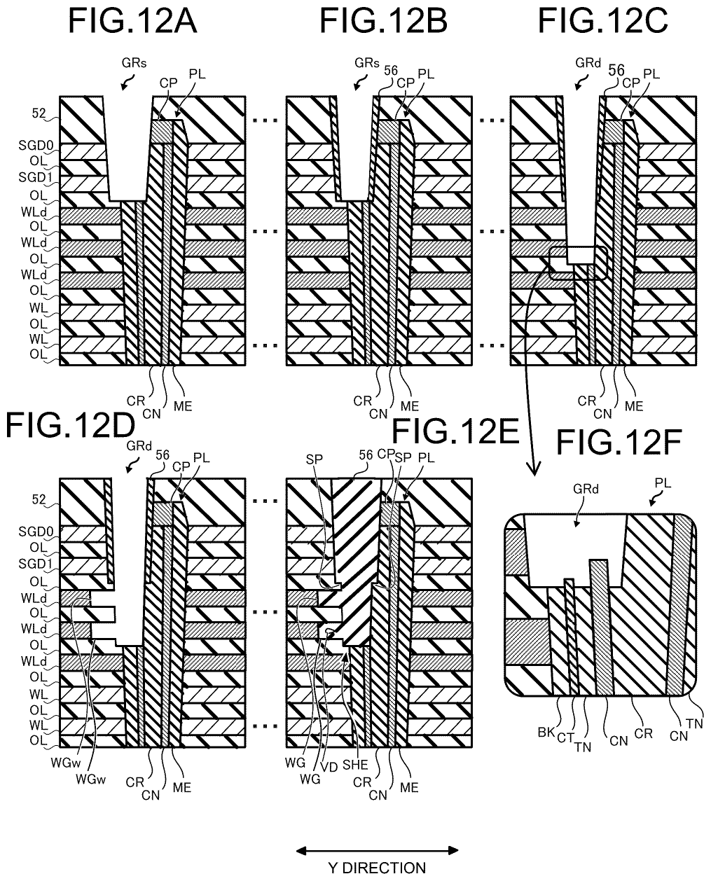

FIGS. 12A to 12F illustrate a procedure of forming the separating layer SHE.

In addition, in the example illustrated in FIGS. 12A to 12F, similarly to FIGS. 3A to 3C described above, for example, two selection gate lines SGD0 and SGD1 from the upper layer side of the stacked body LM are formed. Further, the stacked body LM includes three dummy word lines WLd in lower layers of the selection gate lines SGD0 and SGD1.

As illustrated in FIG. 12A, a groove GRs that penetrating through the conductive layers 29 on the upper layer side of the stacked body LM that are desired to function as the selection gate lines SGD, and extends in the stacked body LM in the direction running along the X direction is formed. In the formation of the groove GRs, dry etching such as reactive ion etching (RIE), for example, can be used.

At this time, to cause the groove GRs to surely penetrate through the selection gate lines SGD0 and SGD1, it is preferable that the bottom surface of the groove GRs reaches some midpoint in the insulating layer OL arranged immediately below the selection gate line SGD 1. The bottom surface of the groove GRs may reach the word line WLd in the uppermost layer. In this manner, by arranging the dummy word lines WLd between the selection gate lines SGD and the word lines WL, it is possible to obtain a margin in forming the separating layer SHE.

As illustrated in FIG. 12B, the insulating layers 56 such as oxide silicon layers are formed on side surfaces of the groove GRs that face in the Y direction. At this time point, the insulating layers 56 cover the side walls of the groove GRs with a predetermined thickness without being completely charged into the groove GRs.

As illustrated in FIG. 12C, a groove GRd having a reach depth falling within the range of the three dummy word lines WLd is formed by performing additional dry etching on the groove GRs of the side walls are covered by the insulating layers 56. At this time, it is preferable that the groove GRd does not penetrate through the word line WLd in the lowermost layer immediately above the word line WL. By the remaining word line WLd, it is possible to mitigate the influence of electric fields between the memory cell MC and the selection gate STD.

In the example illustrated in FIG. 12C, the groove GRd penetrating through the two word lines WLd on upper layer side among the three word lines WLd, and reaching some midpoint in the insulating layer OL sandwiched between the second and third word lines WLd is formed.

As illustrated in the enlarged view in FIG. 12F, by processing that uses dry etching or the like, unevenness attributed to different material layers included in the pillar PL can be generated on the bottom surface of the groove GRd.

More specifically, the charge accumulation layer CT is a silicon nitride layer or the like, for example, the channel layer CN is a semiconductor layer or the like, for example, and these include materials different from those of the block insulating layer BK, the tunnel insulating layer TN, and the core layer CR being oxide silicon layers or the like, for example. Because the processing speed by dry etching varies among these different material layers, unevenness is sometimes generated on the bottom surface of the groove GRd as described above.

In addition, in the example illustrated in FIG. 12F, FIG. 12F illustrates a state in which the charge accumulation layer CT and the channel layer CN protrude from the bottom surface of the groove GRd because their etching rates are lower than those of the block insulating layer BK, the tunnel insulating layer TN, and the core layer CR. Nevertheless, an etching rate relationship between different material layers can vary depending on a plasma source and etching conditions to be used in dry etching. Thus, the bottom surface of the groove GRd can have an unevenness shape different from that in FIG. 12F.

As illustrated in FIG. 12D, after the formation of the groove GRd using dry etching or the like, the groove GRd is processed by wet etching using medicinal solution solving metal such as tungsten or molybdenum. The dummy word line WLd exposed to the side wall of the groove GRd is accordingly retracted by a predetermined distance, and a wing portion WGw is formed. In a portion in which the pillar PL and the groove GRd overlap with each other, the wing portion WGw is formed on one side in the Y direction of the groove GRd, and on other portions, the wing portions WGw are formed on both sides in the Y direction of the groove GRd.

Wet etching has higher selectivity between different materials as compared with dry etching or the like, for example. Thus, only the word line WLd on the side wall of the groove GRd is retracted with hardly affecting other layers around the groove GRd including, for example, the selection gate lines SGD0 and SGD1 or the like through which the groove GRd penetrate, but which are covered with the insulating layer 56. Further, in wet etching, etching proceeds isotropically unlike dry etching having aeolotropy, for example. Thus, protruding distances of the wing portion WGw on both sides in the Y direction of the groove GRd at least at the same height position are approximately equal.

As illustrated in FIG. 12E, the insulating layer 56 is charged into the groove GRd including the wing portions WGw.

As described above, the separating layer SHE is formed in the stacked body LM, and an upper layer portion of the stacked body LM is segmented into patterns of the plurality of selection gate lines SGD0 and SGD1 by the separating layer SHE. At this time, a part of the inside of the wing portion WGw may enter an uncharged state, and the wing portion WG may include the void VD formed thereinside. Further, the separating layer SHE may include a void formed at a portion corresponding to the groove GRd.

After that, the insulating layer 52 is formed on the top surface of the stacked body LMb, and the plug CH penetrating through the insulating layer 52 to be connected to the pillar PL is formed. Further, the insulating layer 53 is formed on the insulating layer 52, and the bit-line BL to be connected to the pillar PL via the plug CH is formed in the insulating layer 53. Further, a plug to be connected to the contact CC in the step region SR, and an upper layer wire to be connected to the contact CC via the plug are formed. Further, an electrode pad PDb to be connected to the bit-line BL and the upper layer wire is formed.

On the other hand, on the semiconductor board SB different from the support substrate SS on which the stacked body LM is formed, the peripheral circuit CBA is formed and covered with the insulating layer 40. In the insulating layer 40, a contact, a via, a wire, and the like for drawing the peripheral circuit CBA to the surface of the insulating layer 40 are formed, and connected with an electrode pad PDc and the like formed on the surface of the insulating layer 40.

Further, the support substrate SS and the semiconductor board SB are bonded via the insulating layers 50 and 40 respectively included in the substrates, and electrode pads PDb and PDc in the insulating layers 50 and 40 are connected. After that, by polishing and removing the support substrate SS, the source line SL is exposed, and the electrode film EL is connected via the insulating layer 60 in which the plug PG is formed.

As described above, the semiconductor memory device 1 of the embodiment is manufactured.

### (General Overview)

There has been known a technique of a semiconductor memory device such as a three-dimensional nonvolatile memory or the like that enables independent control of memory cells for each segment of selection gate lines by segmenting one or more conductive layers of a stacked body including an uppermost conductive layer, into patterns of selection gate lines by a separating layer. On the other hand, to increase a memory capacity, pillars are arranged in a memory region at high density in a periodic pattern. Thus, in some cases, separating layers are formed at positions overlapping with some pillars of these pillars, and the pillars enter a partially-chipped state.

In the selection gate on the drain side of the partially-chipped pillar, a threshold voltage sometimes drops. The inventor of the present invention has estimated that unevenness that is generated on the bottom surface of a groove becoming a separating layer, when the groove is formed, one of the factors contributing to the threshold voltage of the selection gate. That is, the inventor has considered that, on the bottom surface of a separating layer formed from a groove having unevenness, if a dummy word line or the like gets closer to a channel layer having unevenness with another member, electric field concentration occurs near the channel layer with unevenness due to a voltage applied via the dummy word line.

According to the semiconductor memory device 1 of the embodiment, the separating layer SHE penetrating through lines from the selection gate line SGD to a predetermined word line WLd in the uppermost layer includes the wing portion WG protruding toward the above-described predetermined word line WLd, at least at the height position of the above-described predetermined word line WLd.

With this configuration, it is possible to locate the word line WLd that is close to the bottom surface of the separating layer SHE, away from the channel layer CN having unevenness of the bottom surface of the separating layer SHE, and prevent electric field concentration near the channel layer CN from being deteriorated by the word line WLd. Accordingly, it is possible to improve the electric property of the selection gate STD belonging to the pillar PL.

According to the semiconductor memory device 1 of the embodiment, the separating layer SHE includes the wing portion WG at the height position of the word line WLd on the lower layer side including the above-described predetermined word line WLd, among lines from the selection gate line SGD in the uppermost layer to the predetermined word line WLd.

When the separating layer SHE is formed, after the side surface of the groove GRd on the upper layer side is covered with the insulating layer 56, the wing portion WG is formed by retracting only the word line WLd on the lower layer side as described above. It is therefore possible to locate the word lines WLd including the above-described predetermined word line WLd that are close to the bottom surface of the separating layer SHE, away from the channel layer CN on the bottom surface of the separating layer SHE, without damaging the selection gate lines SGD.

According to the semiconductor memory device 1 of the embodiment, the conductive layer on the lower layer side toward which the wing portion WG of the separating layer SHE protrudes is the dummy word line WLd. In this manner, if the wing portion WG is protruded toward the dummy word line WLd, influence is not exerted on the property of the semiconductor memory device 1.

According to the semiconductor memory device 1 of the embodiment, a dummy word line WLd immediately below the above-described predetermined word line WLd through which the separating layer SHE penetrates also serves as the dummy word line WLd. By ensuring at least one word line WLd through which the separating layer SHE does not penetrate, it is possible to suppress the influence of electric fields between the selection gate STD and the memory cell MC.

According to the semiconductor memory device 1 of the embodiment, at the same height position, protruding distances of the wing portions WG protruding toward both sides in the Y direction are substantially equal to each other. When the separating layer SHE is formed, the wing portion WG is formed by retracting the word line WLd by wet etching having isotropy, as described above. Thus, protruding distances of the wing portions WG at the same height position are substantially equal to each other. In this manner, it is possible to easily form the wing portion WG using wet etching.

According to the semiconductor memory device 1 of the embodiment, partial pillars PL of a plurality of pillars PL overlap with the separating layer SHE in the stacking direction of the stacked body LM on one side in the Y direction.

In this manner, by allowing interference between the separating layer SHE and the partial pillars PL, it is possible to arrange the partial pillars PL at high density without disrupting the periodicity. Further, by restricting a chipped portion of the pillar PL that is caused by the separating layer SHE, to one side in the Y direction of the pillar PL, the selection gate STD and the memory cell MC belonging to the pillar PL including the chipped portion can also function.

According to the semiconductor memory device 1 of the embodiment, the separating layer SHE extends in the direction running along the X direction, at a position between rows of pillars PL neighboring each other in the direction running along the X direction, and at positions overlapping, in the stacking direction of the stacked body LM, with a side of the pillar PL belonging to one row that faces the other row, and a side of the pillar PL belonging to the other row that faces the one row.

By adjusting a positional relationship between the separating layer SHE and the pillars PL in this manner, it is possible to restrict a chipped portion of the pillar PL that is caused by the separating layer SHE, to one side in the Y direction of the pillar PL.

According to the semiconductor memory device 1 of the embodiment, the separating layer SHE includes the insulating layer 56, and electrically separates, in the Y direction, lines from the selection gate line SGD in the uppermost layer to the predetermined word line WLd through which the separating layer SHE penetrates. With this configuration, it is possible to segment the conductive layers on the upper layer side of the stacked body LM into patterns of the plurality of selection gate lines SGD, and independently drive the memory cells MC for each group of several memory cells MC.

According to the semiconductor memory device 1 of the embodiment, the wing portion WG of the separating layer SHE partially includes the void VD. In this manner, even if the wing portion WG includes the void VD, it is possible to obtain an effect of suppressing electric field concentration near the channel layer CN that is caused by the word line WLd.

According to the semiconductor memory device 1 of the embodiment, the separating layer SHE includes the step SP at a boundary portion between the lower layer side portion SHEa extending in the stacked body LM at a height position of the word line WLd on the lower layer side including the wing portion WG, and the upper layer side portion SHEb extending in the stacked body LM at a height position of the selection gate lines SGD on the upper layer side than the lower layer side portion SHEa.

Such a step SP is formed by covering the side surfaces with the insulating layers 56 and then performing additional etching of the groove GRs as described above, when the separating layer SHE is formed. In this manner, because the side surfaces are covered with the insulating layers 56, it is possible to form the wing portion WG in the separating layer SHE without damaging the selection gate lines SGD.

In addition, in the above-described embodiment, the pillar PL is connected with the source line SL on the side surface of the channel layer CN, but the configuration of the pillar PL is not limited to this. For example, the pillar may be configured to be connected to the source line at the lower end of the channel layer by removing the memory layer on the pillar bottom surface.

Further, in the above-described embodiment, the step region SR or the like is arranged at the end in the X direction of the stacked body LM. Nevertheless, the arrangement position of the step region in the stacked body is not limited to this. The step region may be arranged at a central portion of the stacked body, for example, and in this case, a memory region can be arranged at the end of the stacked body LM, for example.

Further, in the above-described embodiment, the stacked body LM having a two-tier structure including the stacked bodies LMa and LMb is included by separately stacking the insulating layers NL and OL twice. Nevertheless, the stacked body may have a one-tier structure or a structure including three or more tiers. By increasing the number of tiers, it is possible to further increase the number of the stacked word line WL.

Further, in the above-described embodiment, the semiconductor memory device 1 is formed by bonding the stacked body LM in which the pillars PL the contact CC, and the like are formed, and the semiconductor board SB on which the peripheral circuit CBA is formed. Nevertheless, a semiconductor memory device may be obtained by forming a peripheral circuit on a semiconductor board, and forming components such as a stacked body above the peripheral circuit via a source line. Alternatively, a semiconductor memory device may be obtained by forming a peripheral circuit on a semiconductor board, and forming components such as a stacked body at a position on the same semiconductor board that is deviated from the peripheral circuit.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of conductive layers is stacked with being separated from each other; and
a plate-like portion extending in the stacked body in a stacking direction of the stacked body and in a first direction intersecting with the stacking direction, and penetrating through conductive layers from an uppermost conductive layer to an N-th (N is an integer of 1 or more) conductive layer, among the plurality of conductive layers,
wherein the plate-like portion includes a wing portion protruding toward the N-th conductive layer, at least at a height position of the N-th conductive layer among the plurality of conductive layers.

2. The semiconductor memory device according to claim 1,
wherein the plate-like portion each includes the wing portion at height positions of conductive layers on a lower layer side that includes the N-th conductive layer, among the conductive layers from the uppermost conductive layer to the N-th conductive layer.

3. The semiconductor memory device according to claim 2,
wherein the conductive layers on the lower layer side toward each of which the wing portion protrudes are dummy word lines.

4. The semiconductor memory device according to claim 3,
wherein, among the plurality of conductive layers, an (N+1) th conductive layer from the uppermost conductive layer is a dummy word line.

5. The semiconductor memory device according to claim 1,
wherein, the wing portion is included in wing portions protruding toward both sides in a second direction intersecting with the stacking direction and the first direction at a same height position, and
protruding distances of the wing portions protruding toward both sides in the second direction at a same height position are substantially equal to each other.

6. The semiconductor memory device according to claim 1, further comprising
a plurality of pillars each including a semiconductor layer extending in the stacked body in the stacking direction,
wherein some pillars of the plurality of pillars overlap with the plate-like portion in the stacking direction on one side in a second direction intersecting with the stacking direction and the first direction.

7. The semiconductor memory device according to claim 6,
wherein at least further partial pillars of the some pillars belong to:
a first row extending in the first direction; or
a second row neighboring the first row and extending in the first direction, and
the plate-like portion extends in the first direction at a position between the first and second rows, and overlaps in the stacking direction with a second row side of a pillar belonging to the first row, and a first row side of a pillar belonging to the second row.

8. The semiconductor memory device according to claim 7,
wherein the plurality of pillars has staggered arrangement when viewed from the stacking direction.

9. The semiconductor memory device according to claim 1,
wherein the plate-like portion includes an insulating layer, and
the plate-like portion electrically separates the conductive layers from the uppermost conductive layer to the N-th conductive layer through which the plate-like portion penetrates, in a second direction intersecting with the stacking direction and the first direction.

10. The semiconductor memory device according to claim 9,
wherein the wing portion partially includes a void.

11. The semiconductor memory device according to claim 2,
wherein the plate-like portion includes:
a first portion extending in the stacked body at the height positions of the conductive layers on the lower layer side in which the plate-like portion includes the wing portion;
a second portion extending in the stacked body at a height position of a conductive layer on an upper layer side than the first portion, and
a step at a boundary portion between the first portion and the second portion.

12. The semiconductor memory device according to claim 11,
wherein a width at an upper end of the first portion in a second direction intersecting with the stacking direction and the first direction is narrower than a width at a lower end of the second portion in the second direction.

13. A manufacturing method of a semiconductor memory device, comprising:
forming a stacked body in which a plurality of conductive layers is stacked with being separated from each other;
forming, by dry etching, a groove extending in the stacked body in a stacking direction of the stacked body and in a first direction intersecting with the stacking direction, and penetrating through conductive layers from an uppermost conductive layer to an M-th (M is an integer of 1 or more) conductive layer, among the plurality of conductive layers;
forming a first insulating layer covering a side surface of the groove in a second direction intersecting with the stacking direction and the first direction;
causing the groove to penetrate through conductive layers from the uppermost conductive layer to an N-th (N is an integer larger than M) conductive layer, among the plurality of conductive layers, by additional dry etching of the groove in which the first insulating layer is formed;
among the plurality of conductive layers, by wet etching via the groove, retracting conductive layers exposed in the second direction to the side surface of the groove, from the side surface of the groove, the conductive layers including the N-th conductive layer; and
by filling a second insulating layer into the groove, forming a plate-like portion including a wing portion each protruding toward the conductive layers including the N-th conductive layer at height positions of the conductive layers including the N-th conductive layer.

14. The manufacturing method of a semiconductor memory device according to claim 13, further comprising:
forming a plurality of pillars each including a semiconductor layer extending in the stacked body in the stacking direction; and
forming the groove at a position overlapping, in the stacking direction, with one side in a second direction intersecting with the stacking direction and the first direction, in some pillars of the plurality of pillars.

15. The manufacturing method of a semiconductor memory device according to claim 13, further comprising:
forming a plurality of pillars each including a semiconductor layer extending in the stacked body in the stacking direction, in such a manner as to belong to:
a first row extending in the first direction; or
a second row neighboring the first row and extending in the first direction; and
forming the groove extending in the first direction at a position between the first and second rows, and overlapping, in the stacking direction, with a second row side of a pillar belonging to the first row, and a first row side of a pillar belonging to the second row.

16. The manufacturing method of a semiconductor memory device according to claim 15, further comprising:
forming the plurality of pillars in such a manner as to have staggered arrangement when viewed from the stacking direction.
